(19) United States
(12) Patent Application Publication
(10) Pub. No.: US 2026/0074676 A1
(43) Pub. Date: Mar. 12, 2026

(54) ACOUSTIC WAVE DEVICE SUPPRESSING SPURIOUS WAVE IN LAMB WAVE AND FILTER INCLUDING THE SAME

(71) Applicant: WISOL CO., LTD., Osan-si (KR)

(72) Inventors: Hun Yong LEE, Osan-si (KR); Yoshikazu KIHARA, Osan-si (KR)

(73) Assignee: WISOL CO., LTD., Osan-si (KR)

(21) Appl. No.: 19/319,472

(22) Filed: Sep. 4, 2025

(30) Foreign Application Priority Data
Sep. 11, 2024 (KR) 10-2024-0124077

(51) Int. Cl. H03H 9/64; H03H 9/02; H03H 9/25

(52) U.S. Cl. CPC H03H 9/6489; H03H 9/02228; H03H 9/02574; H03H 9/02992; H03H 9/25

(57) ABSTRACT

An acoustic wave device for suppressing spurious waves in Lamb waves, and a filter including the same, are provided. The acoustic wave device comprises a support substrate; a piezoelectric substrate supported by the support substrate and defining a first resonator region; and a first resonator and a second resonator disposed in the first resonator region, each comprising a plurality of interdigital transducer (IDT) electrodes and electrically connected to each other. The support substrate includes a first cavity formed beneath the first resonator and a second cavity formed beneath the second resonator, wherein the first cavity and the second cavity are interconnected within the support substrate.

### FIELD OF THE INVENTION

The present invention relates to an acoustic wave device for suppressing spurious waves in Lamb waves and a filter including the same, and more specifically, to an acoustic wave device capable of suppressing spurious wave components propagating along a piezoelectric substrate by forming a cavity within a support substrate in contact with the piezoelectric substrate, and a filter including such a device.

### BACKGROUND OF THE RELATED ART

In wireless communication devices, resonators and filters utilizing surface acoustic waves (SAW) and bulk acoustic waves (BAW) have been widely used. However, with the advent of 5G standards and subsequent wireless communication standards that utilize high-frequency bands above 2.7 GHz, there is a growing demand for resonators capable of handling high frequencies, wide bandwidths, and high power.

In particular, Patent Document 1 proposes an acoustic wave resonator that employs Lamb waves, which are a type of plate wave, to enhance frequency characteristics toward higher frequencies.

### DISCLOSURE OF THE INVENTION

### Technical problem

However, in the device disclosed in Patent Document 1, degradation of device performance occurs due to spurious waves generated in the Lamb wave, and thus a technical solution to address this issue is required.

The technical problem to be solved by the present invention is to provide a resonator having a cavity configured to sufficiently suppress spurious waves generated in an acoustic wave device using Lamb waves, and a filter including the same.

The technical problems of the present invention are not limited to those mentioned above, and other technical problems not explicitly stated will be clearly understood by those skilled in the art from the description below.

### Technical Solution

To solve the aforementioned technical problems, an acoustic wave device for suppressing spurious waves in a Lamb wave according to an embodiment of the present invention includes: a support substrate; a piezoelectric substrate supported by the support substrate and defining a first resonator region on the support substrate; and a first resonator and a second resonator, which are disposed in the first resonator region of the piezoelectric substrate, each including a plurality of interdigital transducer (IDT) electrodes and electrically connected to each other. The support substrate includes a first cavity formed beneath the first resonator and a second cavity formed beneath the second resonator, wherein the first and second cavities are interconnected within the support substrate.

In some embodiments of the present invention, the piezoelectric substrate further defines a second resonator region, and a third resonator comprising a plurality of IDT electrodes is further included in the second resonator region. The support substrate further includes a third cavity formed beneath the third resonator, and the first cavity and the third cavity are not connected to each other. The first or second resonator and the third resonator may propagate Lamb waves in mutually different frequency bands.

In some embodiments of the present invention, the support substrate may include a partition wall that separates the first cavity from the third cavity.

In some embodiments of the present invention, each of the first to third resonators includes a bus bar, and the partition wall may be disposed to overlap, in a depth direction of the support substrate, with at least one of the bus bars of the first to third resonators.

In another embodiment of the present invention for solving the above-described technical problem, an acoustic wave device for suppressing spurious waves in Lamb waves includes: a support substrate; a piezoelectric substrate supported by the support substrate and having a first resonator region defined thereon; and a first resonator and a second resonator, each including a plurality of interdigital transducer (IDT) electrodes, disposed in the first resonator region of the piezoelectric substrate.

The support substrate includes a first cavity formed beneath the first resonator and a second cavity formed beneath the second resonator.

The first cavity and the second cavity are not connected to each other, and the Lamb waves propagated by the first and second resonators have mutually different frequency bands.

In some embodiments of the present invention, the support substrate may include a partition wall formed between the first cavity and the second cavity.

In some embodiments of the present invention, the first and second resonators may each include a bus bar, and the partition wall may be arranged to overlap, in the depth direction of the support substrate, with at least one of the bus bars of the first and second resonators.

Other specific details of the embodiments are included in the detailed description and drawings.

### Effects of the invention

The acoustic wave device for suppressing spurious waves in Lamb waves according to the present invention can effectively suppress spurious waves of Lamb waves by allowing resonators that propagate Lamb waves in the same frequency band to share a cavity formed beneath them.

The effects of the present invention are not limited to those mentioned above, and other effects not explicitly stated can be clearly understood by those skilled in the art from the entirety of this specification.

### DESCRIPTION OF DRAWINGS

FIG. 1 is a diagram for illustrating an acoustic wave device for suppressing spurious waves in Lamb waves according to an embodiment of the present invention.

FIG. 2 is a cross-sectional view taken along line A–A′ of FIG. 1.

FIG. 3 is a cross-sectional view taken along line B–B′ of FIG. 1.

### EMBODIMENTS OF THE INVENTION

The advantages and features of the present invention and the method for achieving them will become clear by referring to the embodiments described below in detail together with the accompanying drawings. However, the present invention is not limited to the embodiments disclosed below and will be implemented in various different forms. These embodiments are provided only to make the disclosure of the present invention complete and to fully inform those skilled in the art of the scope of the present invention, and the present invention is only defined by the scope of the claims. Like reference numerals refer to like elements throughout the specification.

“And/or” includes each of the mentioned items and all combinations of one or more of the mentioned items.

The terms used in this specification are to describe the embodiments and are not to limit the present invention. In this specification, singular forms also include plural forms unless specially stated otherwise in the phrases. The terms “comprises” and/or “comprising” used in this specification means that the mentioned components, steps, operations, and/or elements do not exclude the presence or addition of one or more other components, steps, operations and/or elements.

In addition, throughout the specification, when a part is said to be "connected" to another part, this also includes "indirectly" or "electrically connected" cases with intervention of other members or components therebetween, as well as "directly connected" cases.

In addition, throughout the specification, the description that each layer (film), region, pattern, or structure is formed "above/on" or "beneath/under" a substrate, each layer (film), region, pad, or pattern includes both cases that they are formed directly and formed with intervention of other layers. The criteria for being above/on or beneath/under each layer are explained with reference to the drawings.

In addition, expressions such as 'first, second', and the like are only used to distinguish a plurality of components, and do not limit the sequence of the components or other features.

In addition, the flowcharts shown in the drawings merely illustrate an exemplary sequence for achieving the most desirable results in implementing the present invention. It is understood that additional steps may be added or certain steps may be omitted as necessary.

Unless defined otherwise, all the terms (including technical and scientific terms) used in this specification may be used as meanings that can be commonly understood by those skilled in the art. In addition, terms defined in commonly used dictionaries are not interpreted ideally or excessively unless clearly and specifically defined.

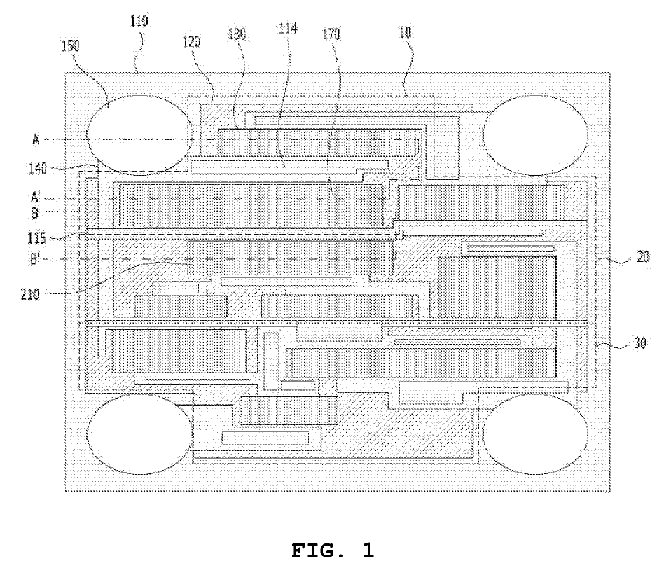

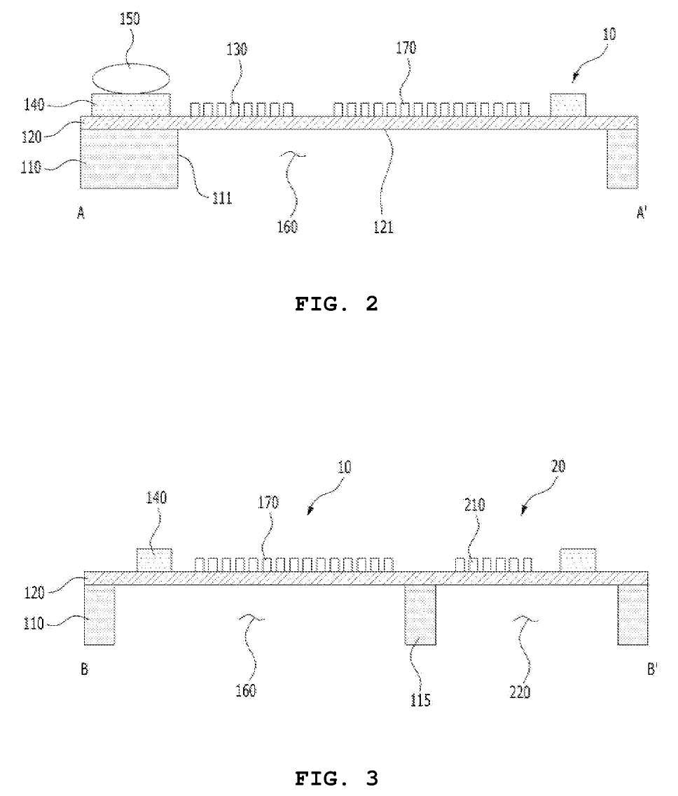

FIG. 1 is a plan view illustrating an acoustic wave device for suppressing spurious waves in Lamb waves according to an embodiment of the present invention. FIG. 2 is a cross-sectional view taken along line A–A′ of FIG. 1, and FIG. 3 is a cross-sectional view taken along line B–B′ of FIG. 1.

Referring to FIGS. 1 through 3, the acoustic wave device 100 according to an embodiment of the present invention may include a support substrate 110, a piezoelectric substrate 120, interdigital transducer (IDT) electrodes 130, pads 140, bumps 150, and the like.

The support substrate 110 may support the piezoelectric substrate 120, which has a relatively small thickness. The thickness of the support substrate 110 may be greater than that of the piezoelectric substrate 120. The support substrate 110 may include a first cavity 160 and a second cavity 220, formed by removing portions of the support substrate 110. The first cavity 160 and the second cavity 220 may attenuate the acoustic waves generated by the resonators 130, 170, 210.

As partially shown in FIGS. 2 and 3, the upper surfaces of the first cavity 160 and the second cavity 220 are defined by the lower surface of the piezoelectric substrate 120, and the side and bottom surfaces of the cavities 160 and 220 may be defined by the side surfaces of the remaining support substrate 110 after partial removal. Accordingly, the first cavity 160 and the second cavity 220 may each have a sealed structure defined by the lower surface of the piezoelectric substrate 120 and the inner surfaces of the support substrate 110.

At least one partition wall 114, 115 may be formed inside the support substrate 110. The partition walls 114, 115 are portions of the support substrate 110 that remain after forming the first cavity 160 or the second cavity 220, and may contact and support the piezoelectric substrate 120.

Meanwhile, the partition walls 114, 115 may partially overlap, in the depth direction of the support substrate 110, with the bus bars that are components of the resonators 130, 170. Through this configuration, the partition walls can serve a heat dissipation function by conducting heat generated during the operation of the resonators 130, 170. That is, the partition walls 114, 115 are elongated in the longitudinal direction of the resonators 130, 170 not only to support the piezoelectric substrate 120, but also to increase the contact area with the resonators for effective heat dissipation.

The support substrate 110 may include, for example, a semiconductor material such as polycrystalline silicon or amorphous silicon. In another embodiment, the support substrate 110 may be composed of a multilayer film. When the support substrate 110 is formed as a multilayer structure, it may include a configuration of a silicon substrate, a silicon oxide layer, and a silicon nitride layer sequentially formed on the silicon substrate.

The piezoelectric substrate 120 may be disposed on the support substrate 110 and may propagate a Lamb wave, which is a type of plate wave that reflects and travels between the upper and lower surfaces in a region where the IDT electrodes 130 are formed. The piezoelectric substrate 120 may include, for example, materials such as LiTaO₃ (LT) or LiNbO₃ (LN).

A plurality of resonator regions 10, 20, and 30 may be defined on the piezoelectric substrate 120. Each of the resonator regions 10, 20, and 30 defined on the piezoelectric substrate 120 may be distinguished as a region where an independent cavity is formed below the piezoelectric substrate 120.

A first cavity 160 may be formed beneath the first resonator region 10, and a second cavity 220 may be formed beneath the second resonator region 20. In this case, the first cavity 160 and the second cavity 220 may be unconnected to each other. The description that "one cavity is unconnected to another" means that the two cavities are separated by a partition wall 115 that forms part of the support substrate 110. Furthermore, as will be described later, this may indicate that the Lamb waves propagating through the first resonator region 10 above the first cavity 160 and the Lamb waves propagating through the second resonator region 20 above the second cavity 220 exhibit different characteristics.

Resonators 130, 170, 210 may be disposed on the piezoelectric substrate 120. The resonators 130, 170, 210 may be distinguished a first resonator 130 and a second resonator 170 disposed on the first resonator region 10 of the piezoelectric substrate 120, and a third resonator 210 disposed on the second resonator region 20. Each of the resonators 130, 170, 210 may include bus bars formed in parallel along the longitudinal direction, and interdigital transducer (IDT) electrodes alternately extending from the bus bars.

In some embodiments of the present invention, the first resonator 130 and the third resonator 210 may propagate Lamb waves having different characteristics. For example, the first resonator 130 and the third resonator 210 may propagate Lamb waves in different frequency bands.

In contrast, the first resonator 130 and the second resonator 170, which are disposed within the same first resonator region 10, may propagate Lamb waves in the same frequency band.

As such, in the acoustic wave device 100 according to the embodiment of the present invention, the placement of resonators 130, 170 that propagate Lamb waves in the same frequency band on the same first resonator region 10 above the first cavity 160 is intended to suppress spurious Lamb waves generated by the first resonator 130 and the second resonator 170. Meanwhile, resonators 130, 210 that propagate Lamb waves in different frequency bands may be distinguished from each other by being disposed on the first resonator region 10 and the second resonator region 20, which are located respectively above different cavities—the first cavity 160 and the second cavity 220.

Although embodiments of the present invention have been described so far with reference to the accompanying drawings, it will be apparent to those skilled in the art that the present invention may be performed in other forms without departing from the technical spirit or essential characteristics of the present invention. Therefore, the above-described embodiments should be understood as exemplary in all respects and are not limited.

What is claimed is:

1. An acoustic wave device for suppressing spurious waves in a Lamb wave, the device comprising:
a support substrate;
a piezoelectric substrate supported by the support substrate and defining a first resonator region on the support substrate; and
a first resonator and a second resonator disposed in the first resonator region of the piezoelectric substrate, each comprising a plurality of interdigital transducer (IDT) electrodes and electrically connected to each other,
wherein the support substrate includes a first cavity formed beneath the first resonator and a second cavity formed beneath the second resonator, and the first cavity and the second cavity are interconnected within the support substrate.

2. The acoustic wave device according to claim 1,
wherein the piezoelectric substrate further defines a second resonator region in which a third resonator including a plurality of interdigital transducer (IDT) electrodes is disposed;
wherein the support substrate further includes a third cavity formed beneath the third resonator, and the first cavity and the third cavity are not connected to each other; and
wherein the first or second resonator and the third resonator are configured to propagate Lamb waves in different frequency bands.

3. The acoustic wave device according to claim 2, wherein the support substrate includes a partition wall that separates the first cavity from the third cavity.

4. The acoustic wave device according to claim 3,
wherein each of the first to third resonators includes a bus bar,
and the partition wall is disposed to at least partially overlap, in a depth direction of the support substrate, with the bus bar of at least one of the first to third resonators.

5. An acoustic wave device for suppressing spurious waves in Lamb waves, the device comprising:
a support substrate;
a piezoelectric substrate supported by the support substrate and defining a first resonator region on the support substrate; and
a first resonator and a second resonator disposed in the first resonator region of the piezoelectric substrate, each comprising a plurality of interdigital transducer (IDT) electrodes,
wherein the support substrate includes a first cavity formed beneath the first resonator and a second cavity formed beneath the second resonator,
wherein the first cavity and the second cavity are not interconnected within the support substrate, and
wherein the Lamb waves propagated by the first resonator and the second resonator have different frequency bands, respectively.

6. The acoustic wave device according to claim 5, wherein the support substrate includes a partition wall formed between the first cavity and the second cavity.

7. The acoustic wave device according to claim 6, wherein each of the first and second resonators includes a bus bar, and the partition wall is disposed to overlap in the depth direction of the support substrate with at least one of the bus bars of the first and second resonators.
